(19) United States
(12) Patent Application Publication
(10) Pub. No.: US 2015/0013759 A1
(43) Pub. Date: Jan. 15, 2015

(54) MICROCRYSTALLINE SILICON SOLAR CELL STRUCTURE AND MANUFACTURING METHOD THEREOF

(71) Applicant: NATIONAL CHENG KUNG UNIVERSITY, Tainan City (TW)

(72) Inventors: Chie Gau, Tainan City (TW); Yeu-Long Jiang, Taichung City (TW); Pei-Ling Li, Tainan Ctiy (TW)

(21) Appl. No.: 14/310,008

(22) Filed: Jun. 20, 2014

(30) Foreign Application Priority Data
Jul. 11, 2013 (TW) 102124999

(51) Int. Cl. H01L 31/077; H01L 31/0224; H01L 31/18; H01L 31/028; H01L 31/0288

(52) U.S. Cl. CPC H01L 31/077; H01L 31/028; H01L 31/0288; H01L 31/1824; H01L 31/1884; H01L 31/022466
USPC 136/256; 438/97

(57) ABSTRACT

A microcrystalline silicon solar cell structure and a manufacturing method thereof are revealed to comprise a substrate, a n-type semiconductor layer deposited on the substrate, an intrinsic layer deposited on n-type semiconductor layer and a p-type semiconductor layer deposited on the intrinsic layer and a transparent conductive oxide layer on the p-type semiconductor layer, wherein the intrinsic layer also acts as a major light-absorbing layer of the microcrystalline silicon solar cell by doping 8˜12 vppm p-type ions of the group III element therein, which enables to modify the intrinsic layer with slight n type to improve the conversion efficiency of a battery.

### BACKGROUND OF THE INVENTION

1. Fields of the Invention

The present invention relates to a microcrystalline silicon solar cell structure and a manufacturing method thereof by use of a slight doping compensation in a process for deposition of an intrinsic thin film in the microcrystalline silicon solar cell to control gas flow rates of p-type ions in a group III element, so as further to make a substantial increase in the electrical properties under a condition that the crystalline volume fraction of the intrinsic thin film is subject to slight changes, as well as give consideration to characteristics of the microcrystalline solar cell.

2. Descriptions of Related Art

The sun is the source of life, and human beings cannot live without it. Although there are no immediately exhausted crises for the fossil fuels, e.g. oil or coal, on which the life around the world rely, the carbon dioxide emission from the excessive use of the fossil fuel has already caused the serious greenhouse effect to become the culprit in the earth's warming temperatures. Furthermore, as the price of crude oil continued to rise in recent years, looking for alternative energy sources has become imperative. Alternative energy sources, such as wind, hydro, geothermal, biodiesel, solar cells and so on, to be called as green energy, have attracted considerable attention over recent years, among which the solar cell is the most promising due to its high theoretical efficiency and mature technology. In the energy market of the past, the monocrystalline silicon solar cells made of silicon wafers occupy the major supply quotas. However, the shortage of raw materials and the restricted area of the wafer hinder the future development of the monocrystalline silicon solar cell. Furthermore, a thin film solar cell (aka. a second generation solar cell) can be manufactured at a substantial low cost under a large area as most essential advantages, so as to have a potential to be the mainstream in the future energy market.

However, the energy conversion efficiency of the thin film solar cell is lower. Taking an amorphous silicon thin film solar cells for instance, its conversion efficiency is only half of the silicon solar cell, and the power energy per watt for the thin film solar cell requires a larger space and higher cost, which limits indirectly developments thereof. Considering with a view to the global market share of the solar cell in 2005, the thin film solar cell only occupies 6.6% of the solar cell supply. It is not easy to replace the monocrystalline silicon solar cell in a short term. European Photovoltaic Industry Association (EPIA) estimated that the thin film solar cell may only reach a 12% to 20% market share in 2010. However, the cost of the thin film solar cell will be reduced to 5 cents per kilowatt in 2020, much lower than that is any monocrystalline silicon solar cell (i.e. an estimated high cost of the 10 cents per kilowatt in the future), so the thin film solar cell is still a better choice for the person skilled in the art and become a long-term competitive advantage in solar cell market accordingly.

The solar cell can transform solar energy into electrical energy based on the photoelectric effect of materials. The photoelectric effect is resulted from the phenomenon that light shines into a material to increase conductive carriers. In terms of semiconductor materials, as the energy of the light is larger than the energy gap of the semiconductors, the free elector-hole pairs are generated in the interior thereof. However, these elector-hole pairs can be recombined soon or captured by the carriers in the semiconductors to become vanished. If an internal electric field is applied at this time, the carriers will be quickly led out before vanished. The internal electric field is generated in the joint interface between p-type and n-type semiconductors, and a so-called solar cell uses the internal electric field to extract effectively the current to induce the electricity.

As mentioned above, due to a lack of raw materials in the polycrystalline silicon solar cells leading to a serious price rising in recent years, the thin film solar cell using less materials gets more attention. Structurally speaking, the thin film solar cell comprises a transparent conductive oxide layer, a p-type semiconductor layer, an intrinsic layer, and a n-type semiconductor layer all deposited on glass. The transparent conductive oxide layer is used for increasing the light to penetrate into the intrinsic layer to produce more electron-hole pairs, then use the internal electric filed formed by a p-n semiconductor layer to export the carriers from the electrodes. Relative to the monocrystalline silicon solar cell, the major advantage of the microcrystalline silicon solar cell focuses on an unobvious light recession and better electrical properties. In general, with respect to the nature of the microcrystalline silicon in the amorphous and crystalline ratio, the higher the crystalline ratio is, the better the electrical property of the thin film is. The way to increase the crystalline ratio is to increase the ratio of the hydrogen flow in the equipment. However, in practical application, if the intrinsic layer used for light absorption uses a thin film with a high crystalline ratio, the holes will be increased in the thin film. It makes the oxygen contamination in the environment easily enter into the holes, so that the light-absorbing layer of the original intrinsic layer is present in slight n-type after being subject to oxygen contamination, resulting in a depletion of the efficiency in the cell structure. Thus there is a need for the microcrystalline silicon solar cell vendors and educators to find a solution for a microcrystalline silicon solar cell having a high performance under the conditions of slightly changing the crystalline ratio of the thin film, obtaining an excellent electrical properties and taking the battery excellence into account.

### SUMMARY OF THE INVENTION

Therefore it is a primary object of the present invention to provide a microcrystalline silicon solar cell structure and a manufacturing method thereof using a slight doping compensation in a process for deposition of an intrinsic thin film of the microcrystalline silicon solar cell to control gas flow rates of p-type ions in a group III element, so as further to make a substantial increase in the electrical properties under a condition that the crystalline volume fraction of the intrinsic thin film is subject to slight changes, as well as give consideration to characteristics of the microcrystalline solar cell.

In order to achieve the above object, a microcrystalline silicon solar cell structure and a manufacturing method thereof in the present invention includes following steps of depositing a n-type semiconductor layer on a substrate, depositing an intrinsic layer on the n-type semiconductor layer for light adsorption by doping 8-12 vppm p-type ions of the group III element therein, depositing the p-type semiconductor layer on the intrinsic layer and at last depositing a transparent conductive oxide layer on the p-type semiconductor layer. Accordingly, the aforesaid method enables to control the gas flow rate of the doping gas and monitor effectively a dopant concentration of boron ions, so that the crystalline volume fraction will be subject to a slight change under a best dopant concentration of the boron ions and an optimized current density of the microcrystalline silicon thin film be obtained while taking the characteristics of the solar cell device into account. Furthermore, the slight boron doped ions used in the manufacturing method is dissociated from a gas containing boron ions. Such a gas has been widely used in the semiconductor industry without any additional equipment or devices in dissociation of boron ions as required, thus the threshold and cost for the semiconductor mass production can be substantially lowered.

The dopant of the p-type ion is preferably a gaseous boron ion, dissolved from boron hydride (B2H6).

The microcrystalline silicon solar cell has a current density (J_{sc}) ranging from 20 mA/cm² to 28 mA/cm².

In addition, the present invention provides a microcrystalline silicon solar cell structure manufactured by aforesaid method, comprising a substrate, a n-type semiconductor layer deposited on the substrate, an intrinsic layer deposited on the n-type semiconductor layer, a p-type semiconductor layer deposited on the intrinsic layer, and a transparent conductive oxide layer deposited on the p-type semiconductor layer, wherein the substrate can be made of glass, stainless steel or polymeric materials, the intrinsic layer can act as a light absorbing layer of the microcrystalline silicon solar cell by doping 8˜12 vppm p-type ions of the group III element therein for the photocurrent produced by the photovoltaic effect, and the deposition of the transparent conductive oxide layer on the p-type semiconductor layer can be carried out via technologies of physical vapor deposition (PVD) or chemical vapor deposition (CVD) for properties of a high transmittance and a high conductivity.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a flow chart showing steps of an embodiment of a method for manufacturing a microcrystalline silicon solar cell according to the present invention;

FIG. 2 is a schematic cross-sectional drawing showing a microcrystalline silicon solar cell structure of an embodiment to the present invention;

FIG. 3 is a pump suction time and current density diagram of an embodiment of a manufacturing method of the microcrystalline silicon solar cell according to the present invention;

FIG. 4 is a voltage and current density diagram of an embodiment of a manufacturing method of the microcrystalline silicon solar cell according to the present invention;

FIG. 5 a wavelength and quantum efficiency diagram of an embodiment of a manufacturing method of the microcrystalline silicon solar cell according to the present invention.

### DETAILED DESCRIPTION OF THE PREFERRED EMBODIMENT

First, in the following description of the embodiment, it should be understood that when a layer (or film) or a structure is deposited on or under the other substrate, another layer (or film) or another structure, it can be directly deposited in the other substrate, layer (or film), or another substrate, or there are one or more intermediate layers to deposit between both with indirect method. Please refer to the location of each layer in brief description of the figures.

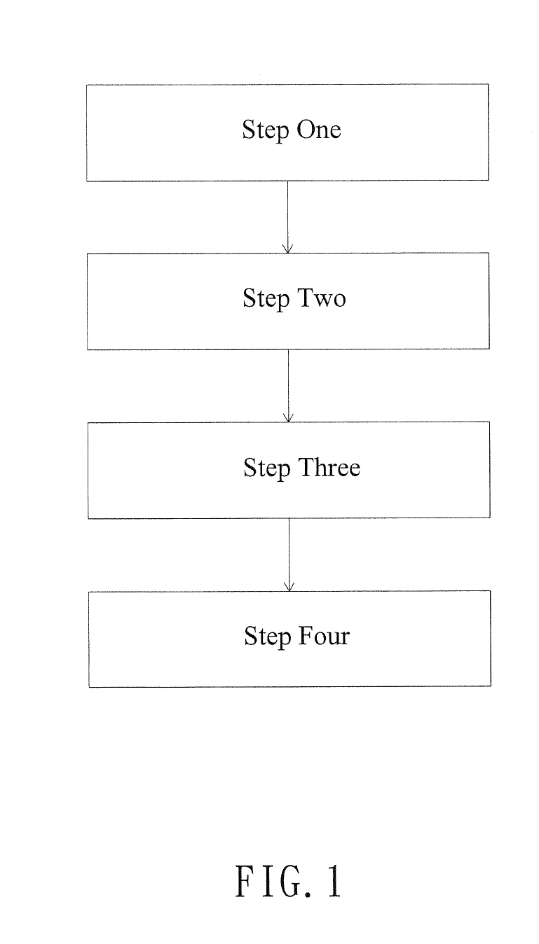

Please refer to FIG. 1, a method for manufacturing a microcrystalline silicon solar cell according to the present invention includes following steps.
Step one (S1): depositing a n-type semiconductor layer 2 on a substrate 1.
Step two (S2): depositing an intrinsic layer 3 on the n-type semiconductor layer 2, wherein the intrinsic layer 3 acts as a light absorbing layer in the solar cell by doping 8-12 vppm p-type ions 31 of the group III element into the intrinsic layer 3. This is because that the crystalline ratio of the intrinsic layer 3 for light absorbing is higher, the electrical performance of the thin film is better. In practical application, if the intrinsic layer 3 uses the thin film with higher crystalline ratio, it is easily contaminated by the outside world, such as oxygen contamination, so that the intrinsic layer 3 is rendered slight n type after the oxygen contamination, resulting in depletion of the efficiency of the cell structure.
Step three (S3): depositing a p-type semiconductor layer 4 on the intrinsic layer 3.
Step four (S4): depositing a transparent conductive oxide layer 5 on the p-type semiconductor layer 4.

That is quite understandable that figures and the dimensions specified in the specification can be modified as the creation and requirement of the particular embodiment without departing from the claim of the present invention. Further, in the embodiments and the detailed description of the figures in the present invention, the same reference characters refer to the same components, and the structure is not necessarily drawn to scale in the figures.

Furthermore, the dopant of the p-type ion 31 is preferably a boron ion, and the boron ion is dissolved from boron hydride (B2H6) in a gaseous state.

Moreover, the microcrystalline silicon solar cell has a current density (J_{sc}) ranging from 20 mA/cm² to 28 mA/cm².

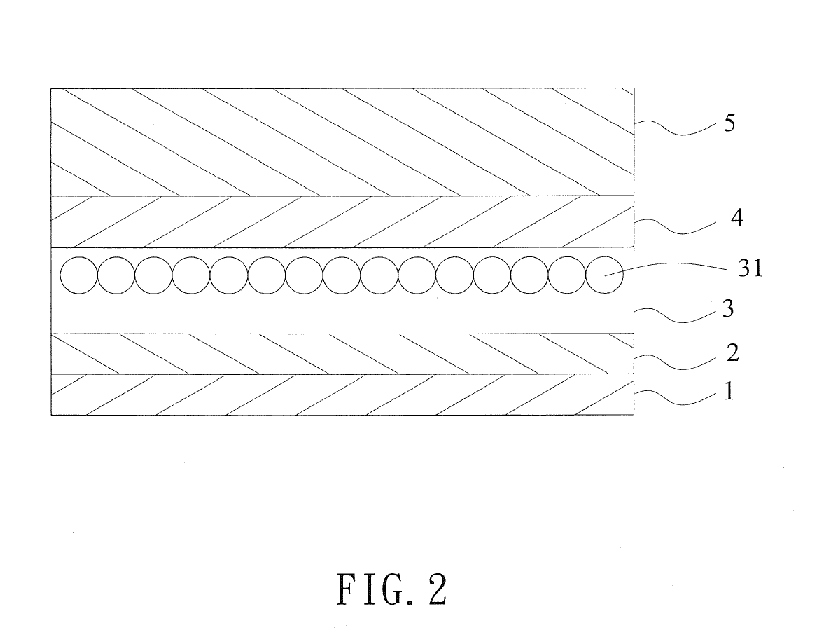

In addition, the present invention provides a structure of the microcrystalline silicon solar. Please refer to FIG. 2, a schematic cross-sectional drawing showing a microcrystalline silicon solar cell structure of an embodiment to the present invention, and the structure comprising:

A substrate 1 can be made of glass, stainless steel or polymeric materials.

A n-type semiconductor layer 2 is deposited on the substrate 1.

An intrinsic layer 3 is deposited on the n-type semiconductor layer 2 for light absorption by doping by 8˜12 vppm p-type ions 31 of the group III element therein, where the dopant of the p-type ion 31 is preferably a boron ion, and the boron ion is dissolved from boron hydride (B2H6) in a gaseous state.

A p-type semiconductor layer 4 is deposited on the intrinsic layer 3.

A transparent conductive oxide layer 5 is deposited on the p-type semiconductor layer 4 via technologies of physical vapor deposition (PVD) or chemical vapor deposition (CVD) for properties of a high transmittance and a high conductivity.

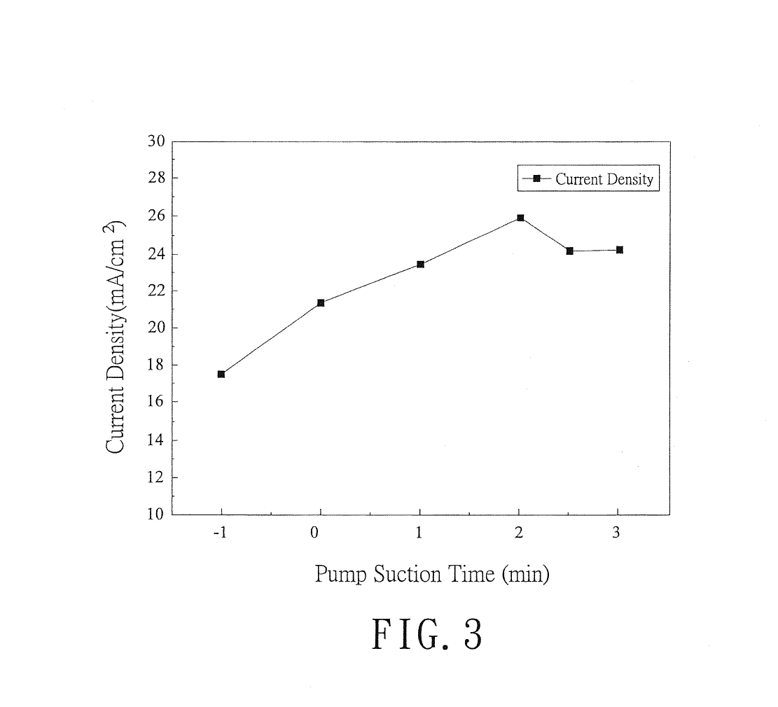

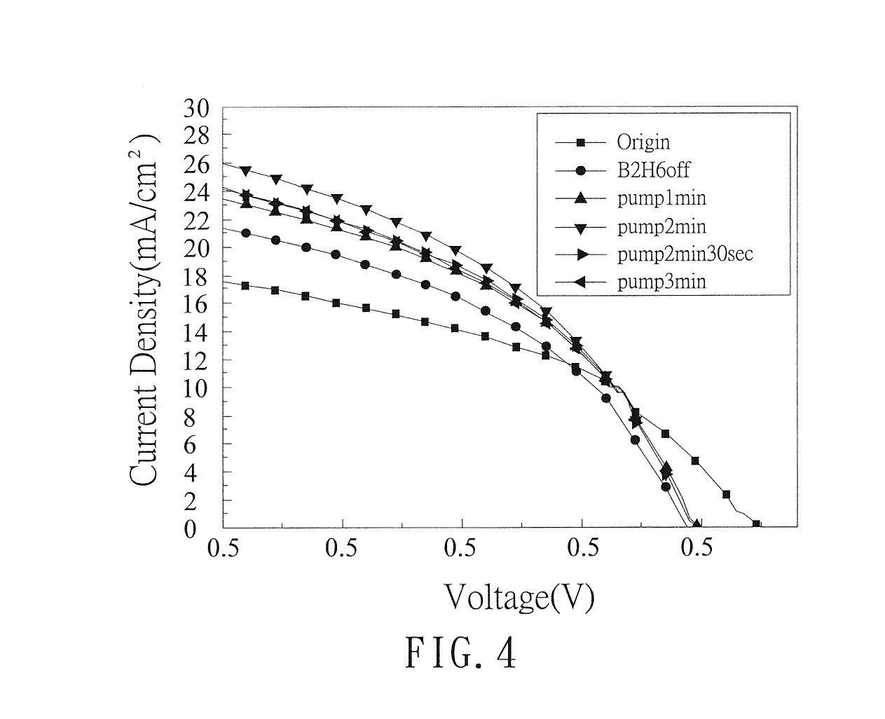

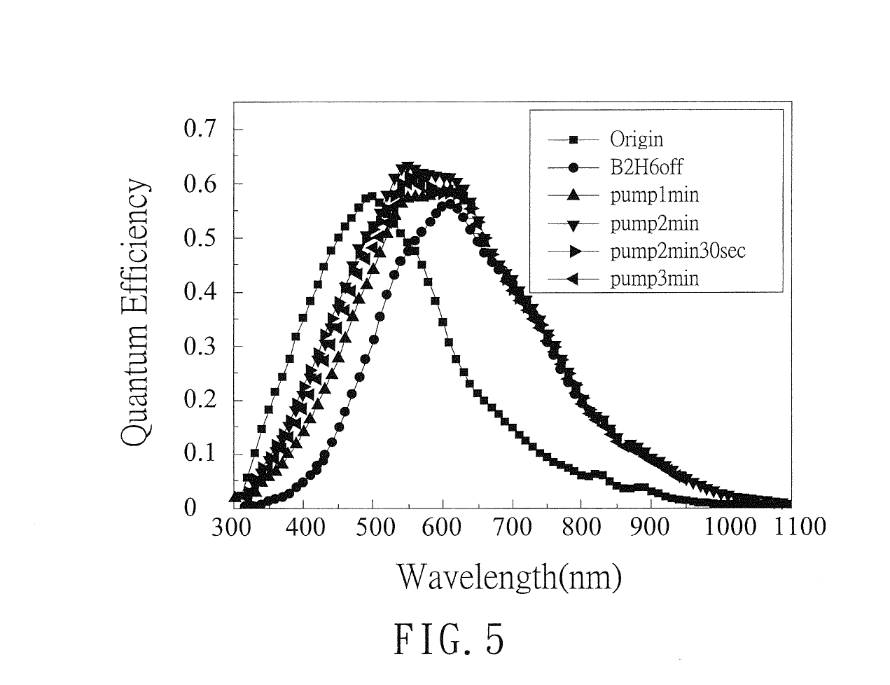

Base on the above implementation of the microcrystalline silicon solar cell, using the method of a mechanical pump pumping the chamber to control a residual volume of the p-type ion 31 in the deposition chamber. It is expected to modify the crystalline ratio to enhance the device electrical performance of a thin film battery. However, the sensing system can be installed extra on the deposition chamber in the particular application, using the precision data to show finer level of the p-type ion 31, where the dopant source of the p-type ion 31 uses the group III element in the chemical table, such as the elements of the boron and gallium. The source of the p-type ion 31 in the present invention is the boron ion dissolved from boron hydride (B2H6) in a gaseous state. It can be found from the table, the method of the boron doping in the present invention enhances the battery performance, where the most obvious change among them is the current density.

| | Current Density | Voltage | Fill Factor |
|---|---|---|---|
| | Jsc(mA/cm²) | Voc(V) | F.F(%) |
| Origin | 17.52 | 0.45 | 56.67 |
| B2H6 off | 21.34 | 0.39 | 56.40 |
| Pump 1 min | 23.42 | 0.40 | 56.80 |
| Pump 2 min | 25.91 | 0.39 | 55.07 |
| Pump 2 min 30 sec | 24.10 | 0.39 | 56.67 |
| Pump 3 min | 24.14 | 0.39 | 55.33 |

Where the original condition (origin) is the measurement result of the battery with the normal condition, other items are the results of the slightly boron doping. Because the present invention controls the residual volume of the boron ion in the deposition chamber with exhausted method. No pump suction (B2H6 off) is to use the plasma to deposit directly the thin film after closing the pump suction, and pump 3 minutes (Pump 3 min) is to use the plasma to deposit thin film after the pump suction three minutes, where the boron component of the condition without pump suction is maximum, and it is minimum of the condition with using plasma to deposit thin film after the pump suction three minutes. The boron components of the pump 1 minute (Pump 1 min), pump 2 minutes (Pump 2 min) and pump 2 minutes and 30 seconds (Pump 2 min 30 sec) are and so on. Please refer to FIG. 3, a pump suction time and current density diagram of an embodiment of a manufacturing method of the microcrystalline silicon solar cell according to the present invention, where the horizontal axis is the pump suction time, and the vertical axis is the current density J_{sc}. The slight boron dopant enhances the current density, and the best result is to pump 2 minutes. When the suction time increases, the current will start to drop from the maximum value of pumping 2 minutes, this result confirms that there is the best concentration with slight boron dopant. Please refer to FIG. 4, a voltage and current density diagram of an embodiment of a manufacturing method of the microcrystalline silicon solar cell according to the present invention, where the square segment denotes the original condition, the circular segment denotes the condition without pump suction, the upper triangular segment denotes the pump 1 min, the lower triangular segment denotes the pump 2 min, the right triangular segment denotes the pump 2 min 30 sec, and the left triangular segment denotes the pump 3 min. The horizontal axis is the voltage, and the vertical axis is the current density. Please refer to FIG. 5, a wavelength and quantum efficiency diagram of an embodiment of a manufacturing method of the microcrystalline silicon solar cell according to the present invention, the horizontal axis is the wavelength, its unit is nanometer (nm), and the vertical axis is the quant efficiency, it is found from the FIG. 4 and FIG. 5, the method of slightly doping boron from the present invention certainly enhances the battery performance and properties.

Compared with techniques available now, the present invention has the following advantages:
1. The microcrystalline silicon solar cell structure and a manufacturing method thereof according to the present invention control the gas flow rate of the doping gas and monitor effectively a dopant concentration of boron ions, so that the crystalline volume fraction will be subject to a slight change under a best dopant concentration of the boron ions and an optimized current density of the microcrystalline silicon thin film be obtained while taking the characteristics of the solar cell device into account.
2. The microcrystalline silicon solar cell structure and manufacturing method thereof according to the present invention the slight boron doped ions used in the manufacturing method is dissociated from a gas containing boron ions. Such a gas has been widely used in the semiconductor industry without any additional equipment or devices in dissociation of boron ions as required, thus the threshold and cost for the semiconductor mass production can be substantially lowered.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A method for manufacturing a microcrystalline silicon solar cell comprising the steps of:
step one: depositing a n-type semiconductor layer on a substrate;
step two: depositing an intrinsic layer on the n-type semiconductor layer, wherein the intrinsic layer acts as a light absorbing layer in the solar cell by doping 8-12 vppm p-type ions of the group III element into the intrinsic layer.
step three: depositing a p-type semiconductor layer on the intrinsic layer;
step four: depositing a transparent conductive oxide layer on the p-type semiconductor layer.

2. The method as claimed in claim 1, wherein the dopant of the p-type ion is preferably a boron ion.

3. The method as claimed in claim 2, wherein the boron ion is dissolved from boron hydride (B2H6) in a gaseous state.

4. The method as claimed in claim 1, wherein the microcrystalline silicon solar cell has a current density (J_{sc}) ranging from 20 mA/cm² to 28 mA/cm².

5. A microcrystalline silicon solar cell structure comprising:
a substrate;
a n-type semiconductor layer deposited on the substrate;
an intrinsic layer deposited on the n-type semiconductor layer for light absorbing by doping 8˜12 vppm p-type ions of the group III element therein;
a p-type semiconductor layer deposited on the intrinsic layer; and
a transparent conductive oxide layer deposited on the p-type semiconductor layer by means of physical or chemical coating method.

6. The structure as claimed in claim 5, wherein the dopant of the p-type ion is preferably a boron ion.

7. The structure as claimed in claim 6, wherein the boron ion is dissolved from boron hydride (B2H6) in a gaseous state.

8. The structure as claimed in claim 5, wherein the microcrystalline silicon solar cell has a current density (J_{sc}) ranging from 20 mA/cm² to 28 mA/cm².
